(19) United States
(12) Patent Application Publication
(10) Pub. No.: US 2024/0429209 A1
(43) Pub. Date: Dec. 26, 2024

(54) TRANSFER SUBSTRATE AND TRANSFER METHOD USING THE SAME

(71) Applicant: Samsung Display Co., LTD., Yongin-si (KR)

(72) Inventor: Jeong Won HAN, Yongin-si (KR)

(73) Assignee: Samsung Display Co., LTD., Yongin-si (KR)

(21) Appl. No.: 18/435,521

(22) Filed: Feb. 7, 2024

(30) Foreign Application Priority Data
Jun. 26, 2023 (KR) 10-2023-0082145

(51) Int. Cl. H01L 25/075; H01L 33/62

(52) U.S. Cl. CPC H01L 25/0753; H01L 33/62; H01L 2933/0066

(57) ABSTRACT

A transfer substrate according to an embodiment includes a base substrate, a magnetic plate disposed on a surface of the base substrate, a mold disposed on another surface of the base substrate and including a plurality of grooves, and a magnetic body disposed in the plurality of grooves of the mold.

### CROSS-REFERENCE TO RELATED APPLICATION(S)

This application claims priority to and benefits of Korean Patent Application No. 10-2023-0082145 under 35 U.S.C. § 119, filed on Jun. 26, 2023, at the Korean Intellectual Property Office, the entire contents of which are incorporated herein by reference.

### BACKGROUND

### 1. Technical Field

Embodiments relate to a transfer substrate and a transfer method using the transfer substrate.

### 2. Description of the Related Art

Recently, display devices having excellent characteristics such as thinness and flexibility have been developed in the field of display technology. The major commercialized display devices are represented by liquid crystal displays (LCD) and organic light emitting diodes (OLED).

Meanwhile, a light emitting diode (LED) is a well-known light emitting device that converts current into light. Fast response time and flexibility are achieved by using a display device with a light emitting device. The light emitting device has various advantages such as long life, low power consumption, excellent initial drive characteristics, and high vibration resistance.

However, in order to implement a large and high-resolution display device with light emitting devices, a very large number of light emitting devices should be accurately assembled or transferred to a wiring board of the display device.

### SUMMARY

Embodiments provide a transfer substrate capable of efficiently transferring a light emitting device and a transfer method using the transfer substrate.

However, embodiments of the disclosure are not limited to those set forth herein. The above and other embodiments will become more apparent to one of ordinary skill in the art to which the disclosure pertains by referencing the detailed description of the disclosure given below.

A transfer substrate according to an embodiment may include a base substrate, a magnetic plate disposed on a surface of the base substrate, a mold disposed on another surface of the base substrate and including a plurality of grooves, and a magnetic body disposed in the plurality of grooves of the mold.

A magnetic body may have a plate shape and may include a plurality of openings, and the mold may be coupled to the plurality of openings of the magnetic body.

The magnetic plate may be disposed in a detachable form away from the base substrate.

The magnetic plate and the magnetic body may have magnets having different polarities.

The magnetic body may be movable inside the mold.

A transfer substrate according to another embodiment may include a base substrate, a conductive plate disposed on a side of the base substrate, a mold disposed on another side of the base substrate and including a plurality of grooves, and a conductive pattern disposed in the plurality of grooves of the mold.

The conductive plate and the conductive pattern may be electrically connected to each other.

The conductive pattern may have a plate shape and may include a plurality of openings, and the mold may be coupled to the plurality of openings of the conductive pattern.

A transfer substrate according to another embodiment may include a mold disposed on a surface of a base substrate and including a plurality of grooves, and a conductive pattern disposed in the plurality of grooves of the mold.

The conductive pattern may have a plate shape and may include a plurality of openings, and the mold may be coupled to the plurality of openings of the conductive pattern.

A transfer method according to an embodiment may include preparing a transfer substrate including a base substrate, a magnetic plate disposed on a surface of the base substrate, a mold disposed on another surface of the base substrate and including a plurality of grooves, and a magnetic body disposed in the plurality of grooves of the mold; attaching a transfer object to the mold, placing the transfer substrate on a transfer stage including a lower magnetic plate, and separating the magnetic plate from the surface of the base substrate.

In the step of separating the magnetic plate from the surface of the base substrate, the magnetic body moves toward the transfer stage to press the transfer object to be closer toward the transfer stage, and thus the transfer object may be transferred to a substrate disposed on the transfer stage.

The method may further include reattaching the magnetic plate to the surface of the base substrate after separating the magnetic plate from the surface of the base substrate.

In the step of reattaching the magnetic plate to the surface of the base substrate, the magnetic body may move to be closer to the magnetic plate and may move to be farther away from the transfer stage.

A transfer method according to another embodiment may include preparing a transfer substrate including a base substrate, a conductive plate disposed on a surface of the base substrate, a mold disposed on another surface of the base substrate and including a plurality of grooves, and a conductive pattern disposed in the plurality of grooves of the mold, attaching a transfer object to the mold, placing the transfer substrate on a transfer stage including a lower conductive plate, and electrically connecting the lower conductive plate and the conductive pattern.

In the step of preparing the transfer substrate, the conductive plate and the transfer substrate are electrically connected to each other, and an electrical attraction may be generated between the conductive plate and the transfer substrate.

The method may further include disconnecting the electrical connection between the conductive plate and the transfer substrate before electrically connecting the lower conductive plate and the conductive pattern, wherein in the step of electrically connecting the lower conductive plate and the conductive pattern, due to an electrical attraction between the lower conductive plate and the conductive pattern, the conductive pattern may move to be closer to the transfer stage to transfer the transfer object to be transferred toward the transfer stage.

The method may further include disconnecting the electrical connection between the lower conductive plate and the conductive pattern and electrically connecting the conductive plate and the conductive pattern after electrically connecting the lower conductive plate and the conductive pattern.

A transfer method according to another embodiment may include preparing a transfer substrate including a base substrate, a mold disposed on a side of the base substrate and including a plurality of grooves, and a conductive pattern disposed in the grooves of the mold, attaching a transfer object to the mold, placing the transfer substrate on a transfer stage including a lower conductive plate, and electrically connecting the lower conductive plate and the conductive pattern.

The transfer method according to another embodiment may include the preparing a transfer substrate including a base substrate, a conductive plate disposed on a surface of the base substrate, a mold disposed on another surface of the base substrate and including a plurality of recesses, and a conductive pattern disposed in the plurality of grooves of the mold and electrically connected to the conductive plate. The method may also include attaching a transfer object to the mold, placing the transfer substrate on a transfer stage, and disconnecting an electrical connection between the conductive plate and the conductive pattern.

According to embodiments, a transfer substrate for efficient transfer of a light emitting device and a transfer method using the transfer substrate are provided.

### BRIEF DESCRIPTION OF THE DRAWINGS

FIG. 1 shows a schematic cross-sectional view of a transfer substrate according to this embodiment.

FIG. 2 shows a schematic plan view of a magnetic body.

FIGS. 3, 4, and 5 show schematic cross-sectional views of grooves of various molds.

FIG. 6 shows a schematic cross-sectional view of a transfer substrate according to another embodiment.

FIG. 7 shows a schematic plan view of a conductive pattern.

FIGS. 8, 9, 10, 11, and 12 show schematic cross-sectional views illustrating a transfer method of a light emitting device according to an embodiment.

FIGS. 13 and 14 show schematic cross-sectional views illustrating a transfer process in case that a magnetic body and a magnetic plate are not included.

FIGS. 15, 16, 17, 18, and 19 show schematic cross-sectional views illustrating a transfer method of a light emitting device according to another embodiment.

FIGS. 20, 21, 22, 23, and 24 show schematic cross-sectional views illustrating a transfer method of a light emitting device according to another embodiment.

FIGS. 25, 26, 27, 28, and 29 show schematic cross-sectional views illustrating a transfer method of a light emitting device according to another embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element (or a layer) is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the X, Y, and Z-axes, and may be interpreted in a broader sense. For example, the DR1-axis, the DR2-axis, and the DR3-axis may be perpendicular to one another, or may represent different directions that are not perpendicular to one another. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein are interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Hereinafter, a transfer substrate according to this embodiment and a transfer method of a light emitting device using the transfer substrate according to the embodiment will be described with reference to drawings.

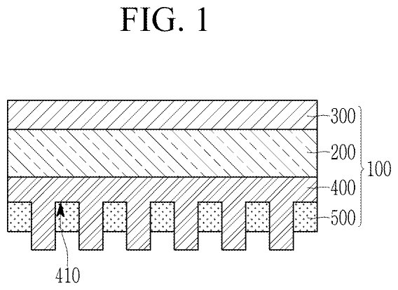

FIG. 1 shows a schematic cross-sectional view of a transfer substrate according to an embodiment. Referring to FIG. 1, the transfer substrate 100 may include a base substrate 200, a magnetic plate 300 positioned on a side of the base substrate 200, a mold 400 positioned on another side of the base substrate 200 and may include multiple grooves 410, and a magnetic body 500 positioned inside the grooves 410 of the mold 400.

As shown in FIG. 1, the transfer substrate 100 may include a magnetic plate 300 and a magnetic body 500 positioned inside the groove 410 of the mold 400, and the magnetic plate 300. and the magnetic force of the magnetic body 500 may be used to transfer the light emitting device. Therefore, in the transfer substrate 100 according to the embodiment, the magnetic plate 300 and the magnetic body 500 may be positioned in a detachable form. The magnetic plate 300 may be detachable, and the magnetic body 500 may be movable within the groove of the mold 400 without being fixed to the groove of the mold 400.

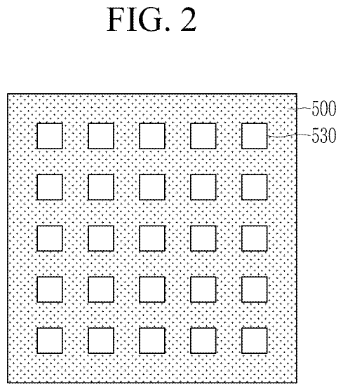

The magnetic body 500 may have a patterned mask shape having an opening engaged with the mold 400. FIG. 2 shows a schematic plan view of the magnetic body 500. The magnetic body 500 may include openings 530 corresponding to the protrusions of the mold 400, and the protrusions of the mold 400 may be fitted into the openings 530 of the magnetic body 500.

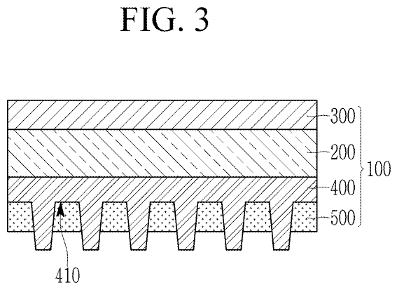

In FIG. 1, the groove 410 of the mold 400 is shown in a rectangular shape, but this is an example, and the shape of the groove 410 of the mold 400 may vary. FIGS. 3, 4, and 5 show schematic cross-sectional views of grooves 410 of various molds 400. The magnetic body 500 positioned inside the groove 410 is also shown.

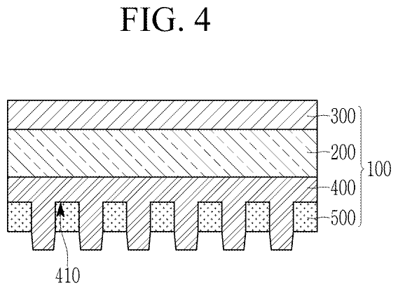

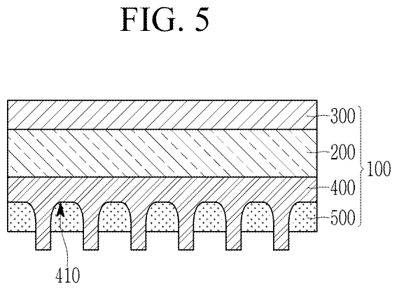

Referring to FIG. 3, a cross-section of the groove 410 may have a trapezoidal shape. In another example, referring to FIG. 4, the shape of the groove 410 may be a rectangle at the inside of the mold 400 and a trapezoid at the edge of the mold 400. In another example, referring to FIG. 5, the cross-section of the groove 410 may include a curved surface. The shape of the groove 410 of FIGS. 3, 4, and 5 is an example, and embodiments are not limited thereto. However, as will be described in detail later, in the transfer process according to the embodiment, the magnetic body 500 may move from the inside of the groove 410 to the outside. Therefore, the outer width of the groove 410 may be greater than the inner width so that the magnetic body 500 may move. In case that the outer width is smaller than the inner width, the magnetic body 500 may not function to operate the transfer during the transfer process.

In the embodiment of FIG. 1, the transfer substrate 100 may include the magnetic plate 300 and the magnetic body 500. In another example, the transfer substrate 100 may be conductive instead of the magnetic plate 300 and the magnetic body 500. A conductive plate 310 and a conductive pattern 510 may be included.

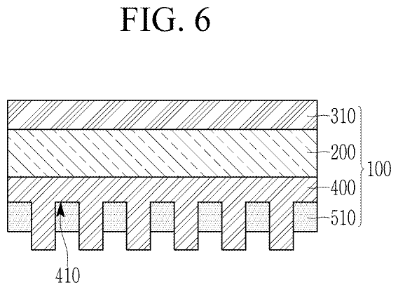

FIG. 6 shows a schematic cross-sectional view of a transfer substrate 100 according to another embodiment. Referring to FIG. 6, the whole transfer substrate 100 is the same as the embodiment of FIG. 1, except that it includes a conductive plate 310 instead of a magnetic plate 300, and a conductive pattern 510 instead of a magnetic body 500.

A detailed description of the same component is omitted for descriptive convenience. For example, the conductive plate 310 may be positioned on one surface of the base substrate 200. The mold 400 may include grooves 410, and the conductive pattern 510 may be positioned in the grooves 410 of the mold. The conductive pattern 510 may be in the form of a patterned mask having an opening that engages the mold 400.

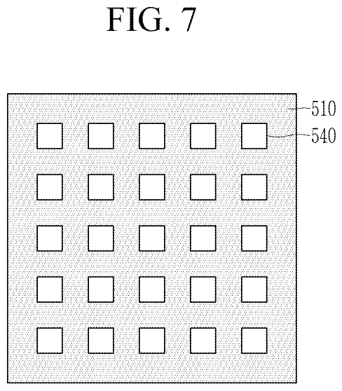

FIG. 7 shows a schematic plan view of the conductive pattern 510. The conductive pattern 510 may include openings 540 corresponding to the protrusions of the mold 400, and the mold 400 may be fitted into the openings 540 of the conductive pattern 510.

In the embodiment of FIG. 6, the conductive plate 310 and the conductive pattern 510 may be electrically connected to each other. Although described later, the light emitting device may be effectively transferred in case that the conductive pattern 510 moves within the groove 410 of the mold 400 due to the electrical attraction between the conductive plate 310 and the conductive pattern 510.

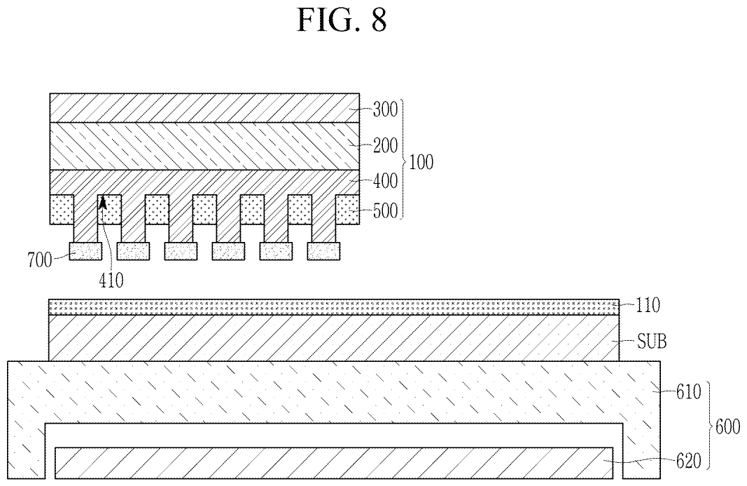

Hereinafter, the transfer method of the light emitting device according to the embodiment will be described in detail with reference to the drawings. FIGS. 8, 9, 10, 11, and 12 show schematic cross-sectional views illustrating a transfer method of a light emitting device according to the embodiment.

Referring to FIG. 8, a transfer substrate 100 and a transfer stage 600 may be prepared. Description of the transfer substrate 100 is the same as that of FIG. 1. For example, the transfer substrate 100 may include a base substrate 200, a magnetic plate 300 positioned on a side of the base substrate 200, a mold 400 positioned on another side of the base substrate 200 and including multiple grooves 410, and a magnetic body 500 positioned inside the groove 410 of the mold 400.

A detailed description of the same components are omitted for descriptive convenience. The light emitting device 700 may be positioned on the protrusion of the mold 400. The light emitting device 700 may be a transfer object, and the light emitting device 700 may be a micro-LED chip. As described above, the magnetic force between the magnetic plate 300 and the magnetic body 500 may cause (or hold) the magnetic body 500 to be positioned inside the groove 410 of the mold 400.

The transfer stage 600 may include a base stage 610 and a lower magnetic plate 620 positioned under the base stage 610. In the pre-transfer step, the lower magnetic plate 620 may be spaced apart from the base stage 610. A substrate SUB may be positioned above the base stage 610, and an adhesive layer 110 may be positioned on the substrate SUB. Since the adhesive layer 110 is positioned on the substrate SUB, the light emitting device 700 positioned on the transfer substrate 100 may be transferred to the substrate SUB.

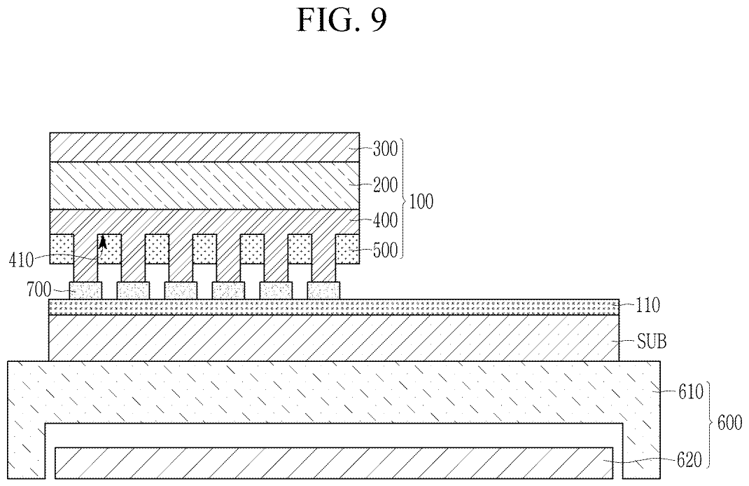

Referring to FIG. 9, the transfer substrate 100 may be moved to a position on the substrate SUB of the light emitting device 700. In this step, the light emitting device 700 may adhere (or be coupled) to the adhesive layer 110 of the substrate SUB. However, in case that the light emitting device is transferred only by this method, there is a problem in that the light emitting device is not sufficiently adhered to the substrate SUB. In the case of this embodiment, the light emitting device may be transferred without omission through a subsequent process by using the magnetic body 500, the magnetic plate 300, and the lower magnetic plate 620.

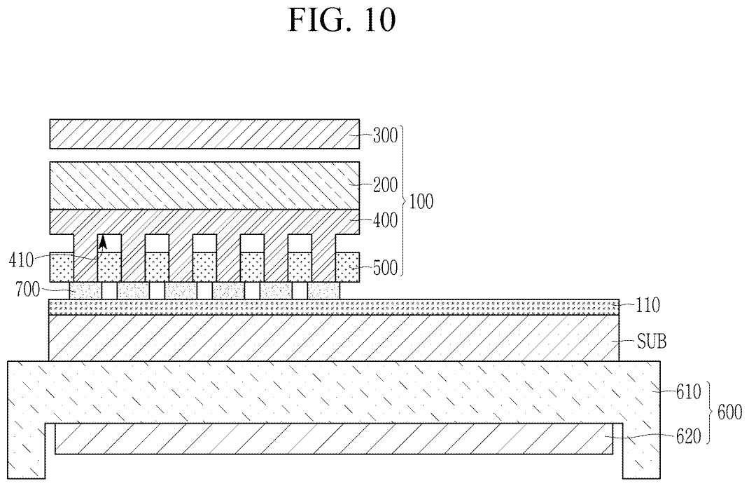

Referring to FIG. 10, the magnetic plate 300 may be separated from the transfer substrate 100, and the lower magnetic plate 620 under the base stage 610 may be attached (or coupled) to the base stage 610. In the previous step of FIG. 9, the magnetic body 500 may be positioned inside the groove 410 of the mold 400 by the magnetic force caused by the magnetic plate 300, but in the step of FIG. 10, the magnetic plate 300 may be separated from the base substrate 200, and the lower magnetic plate 620 may be closer to the magnetic body 500. Thus, the magnetic body 500 may move to the outside of the groove 410 of the mold 400 by the magnetic force caused by the lower magnetic plate 620.

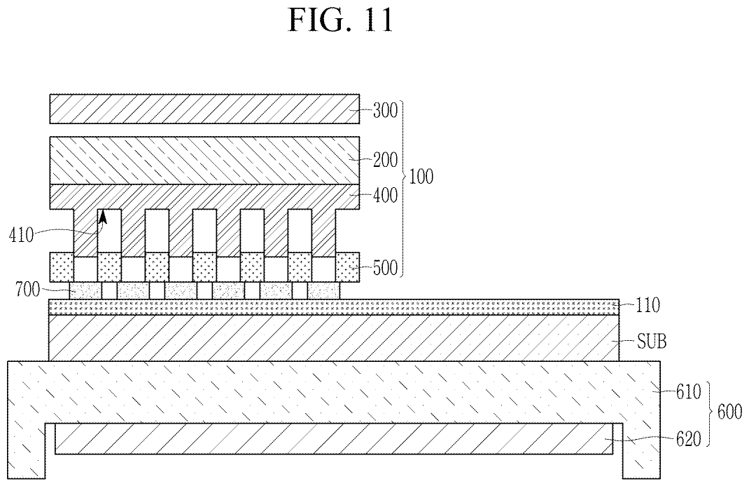

FIG. 11 shows that the magnetic body 500 moves outward from the groove 410 of the mold 400 by the magnetic force caused by the lower magnetic plate 620. By the movement of the magnetic body 500, the magnetic body 500 may push the light emitting device 700, and thus the light emitting device 700 may be separated from the mold 400 and attached (or coupled) to the adhesive layer 110. For example, the light emitting device 700 may be well attached (or coupled) to the adhesive layer 110 by the pressure caused by the movement of the magnetic body 500 toward the substrate SUB, and all transfers may be performed without missing the light emitting device 700.

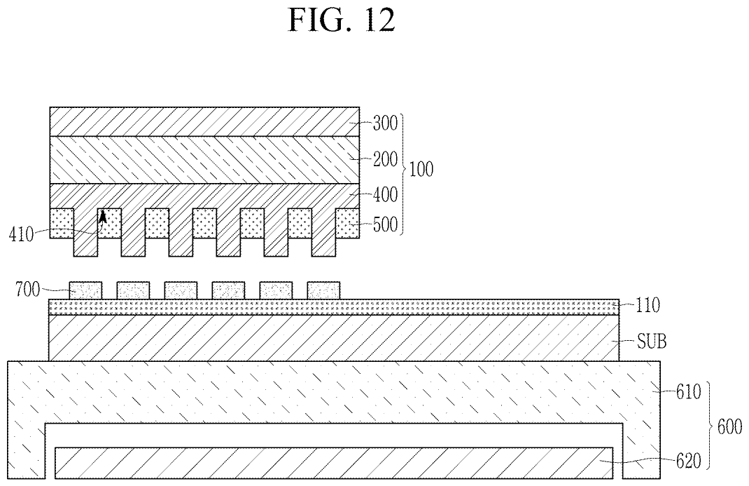

Referring to FIG. 12, the magnetic plate 300 may be placed on (or attached to) a side of the base substrate 200 of the transfer substrate 100 again, and the lower magnetic plate 620 under the transfer stage 600 may be separated from the transfer stage 600. Accordingly, the magnetic body 500 may be positioned inside the groove 410 of the mold 400 by the magnetic force caused by the magnetic plate 300.

For example, the transfer method of the light emitting device according to the embodiment may apply pressure to the light emitting device 700 by using the magnetic force between the magnetic body 500 and the magnetic plate 300 and between the magnetic body 500 and the lower magnetic plate 620, so that the light emitting device 700 may be well transferred.

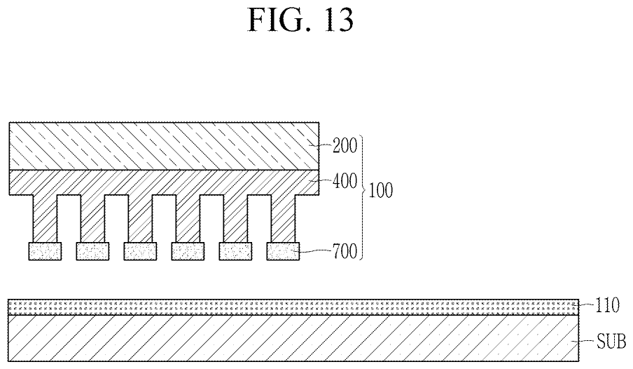

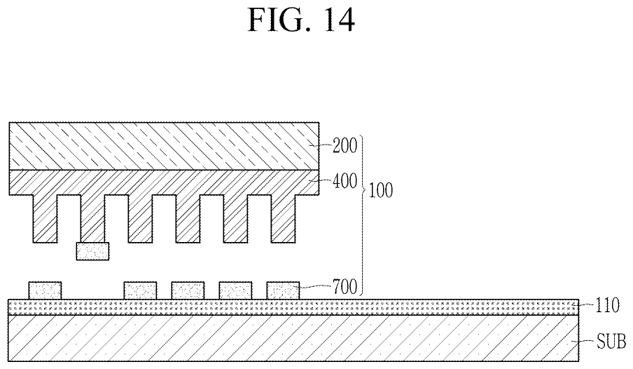

FIGS. 13 and 14 show schematic cross-sectional views illustrating a transfer process where the magnetic body 500 and the magnetic plate 300 are not included. Referring to FIG. 13, the light emitting device 700 may be positioned on the transfer substrate 100 which does not include the magnetic body 500 and the magnetic plate 300.

Referring to FIG. 14, the light emitting device 700 may be transferred to the substrate SUB by placing the transfer substrate 100 on the adhesive layer 110 of the substrate SUB. In this process, as shown in FIG. 14, some of the light emitting devices 700 may remain in the mold 400 without being detached from the mold 400 to be transferred to the substrate SUB. This may occur due to damage to the mold 400 from repeated use, the presence of uneven parts on the substrate SUB, or in case that the transfer substrate 100 and the substrate SUB make weak contact or do not contact at all. In case that some of the light emitting devices 700 are not transferred, a separate repair process may be required.

However, in the transfer method of the light emitting device according to the embodiment, as described above, the light emitting device 700 may be formed by using the magnetic force between the magnetic body 500 and the magnetic plate 300 and between the magnetic body 500 and the lower magnetic plate 620. In case that pressure is applied to the light emitting devices 700 to adhere to the substrate SUB, a problem in which the light emitting device 700 is not transferred to the substrate SUB and remains in the mold 400 may be solved. Therefore, since all of the light emitting devices 700 are transferred, a separate repair process may not be required such that the manufacturing cost may be reduced.

In the above, the process of transferring through magnetic force using the transfer substrate of FIG. 1 has been described, but in another embodiment, transfer through electrical attraction may be performed using the transfer substrate of FIG. 6.

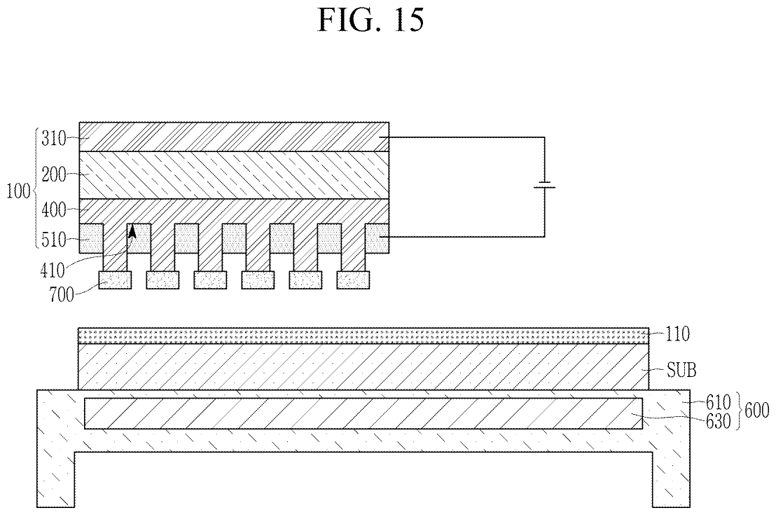

FIGS. 15, 16, 17, 18, and 19 show schematic cross-sectional views illustrating a transfer method of a light emitting device according to another embodiment.

Referring to FIG. 15, a transfer substrate 100 and a transfer stage 600 may be prepared. Description of the transfer substrate 100 is the same as that of FIG. 6. For example, the transfer substrate 100 may include the base substrate 200, the conductive plate 310 positioned on a surface of the base substrate 200, the mold 400 positioned on another surface of the base substrate 200 and including grooves 410, and the mold 400 may include a conductive pattern 510 positioned inside the groove 410. A detailed description of the same component is omitted for descriptive convenience. The light emitting device 700 may be positioned on the protrusion of the mold 400. The light emitting device 700 may be a transfer object, and the light emitting device 700 may be a micro-LED chip. As described above, the conductive plate 310 and the conductive pattern 510 may be electrically connected to each other. For example, voltages opposite to each other may be applied to the conductive plate 310 and the conductive pattern 510. For example, in case that a voltage is applied to the conductive plate 310, a positive voltage may be applied to the conductive pattern 510. The conductive pattern 510 may be positioned inside the groove 410 of the mold 400 by this electrical attraction.

The transfer stage 600 may include a base stage 610 and a lower conductive plate 630 positioned inside the base stage 610. In FIG. 15, the lower conductive plate 630 is illustrated as being positioned inside the base stage 610. However, in another example, the lower conductive plate 630 may be positioned below the base stage 610. The lower conductive plate 630 may receive current.

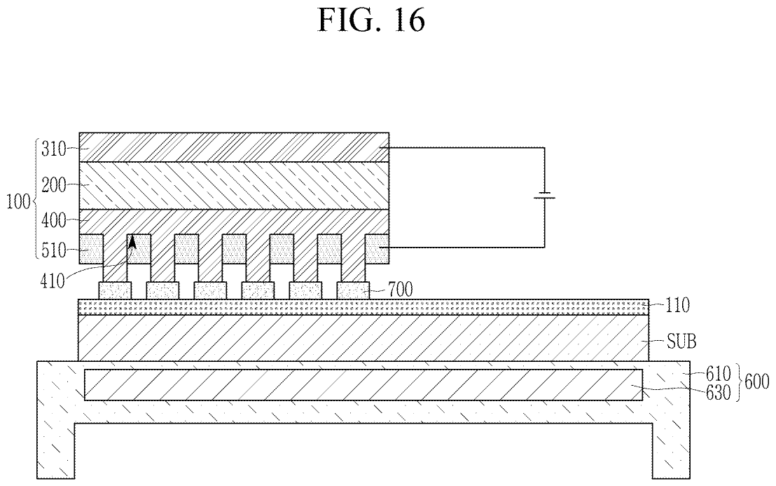

Referring to FIG. 16, the transfer substrate 100 may be moved to place the light emitting device 700 on the substrate SUB. In this step, the light emitting device 700 may adhere to the adhesive layer 110 of the substrate SUB. However, in case that the light emitting device is transferred only by this method, there is a problem in that the light emitting device is not sufficiently adhered to the substrate SUB. In the case of this embodiment, pressure may be applied to the light emitting device 700 through a subsequent process by using the electrical attraction of the conductive plate 310, the conductive pattern 510, and the lower conductive plate 630, so that the light emitting device may be transferred without missing the light emitting device 700.

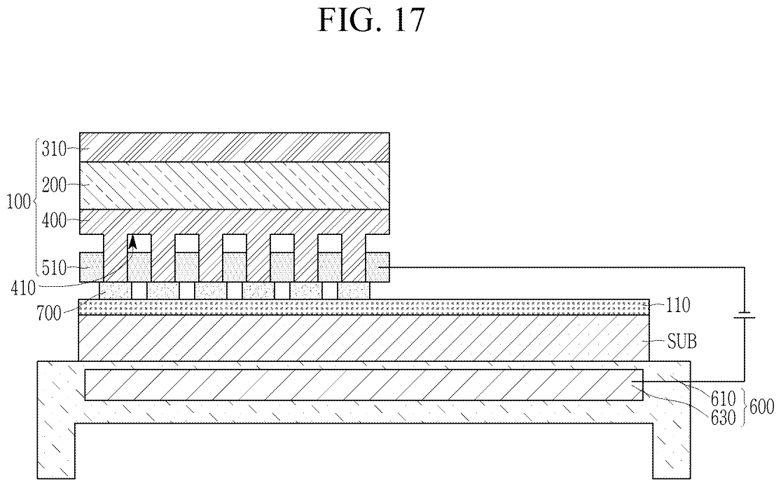

Referring to FIG. 17, in the step of FIG. 17, the electrical connection between the conductive plate 310 and the conductive pattern 510 may be released or disconnected from each other, and the conductive pattern 510 and the lower conductive plate 630 may be electrically connected to each other. For example, opposite voltages may be applied to the lower conductive plate 630 and the conductive pattern 510, respectively. For example, in case that a positive voltage is applied to the lower conductive plate 630, a negative voltage may be applied to the conductive pattern 510. Therefore, the electrical attraction between the conductive plate 310 and the conductive pattern 510 may be reduced, and the electrical attraction may be formed between the lower conductive plate 630 and the conductive pattern 510. Thus, the conductive pattern 510 may be lowered, and the conductive pattern 510 may move to a position close to the conductive plate 630. For example, the conductive pattern 510 may move outside the groove 410 of the mold 400.

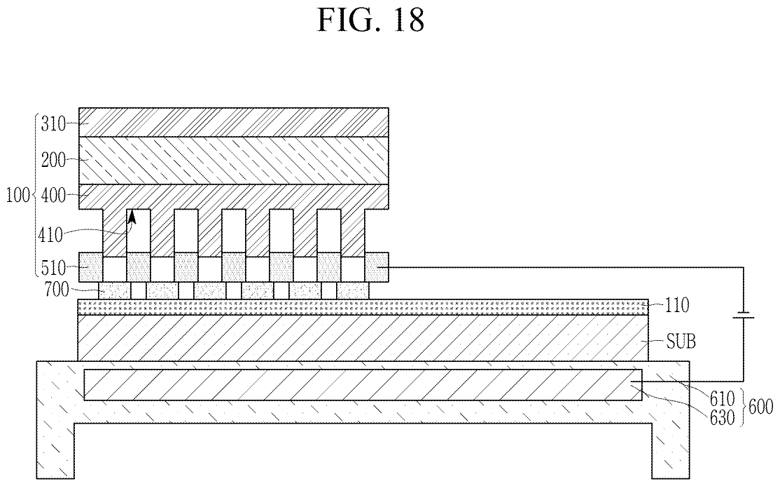

FIG. 18 shows that the conductive pattern 510 is moved out of the groove 410 of the mold 400 by electrical attraction with the lower conductive plate 630. By the movement of the conductive pattern 510, the conductive pattern 510 may push the light emitting device 700, and thus the light emitting device 700 may be separated from the mold 400 and attached (or coupled) to the adhesive layer 110. For example, the light emitting device 700 may be well attached (or coupled) to the adhesive layer 110 by the pressure caused by the movement of the conductive pattern 510, and all transfers may be performed without missing the light emitting device 700.

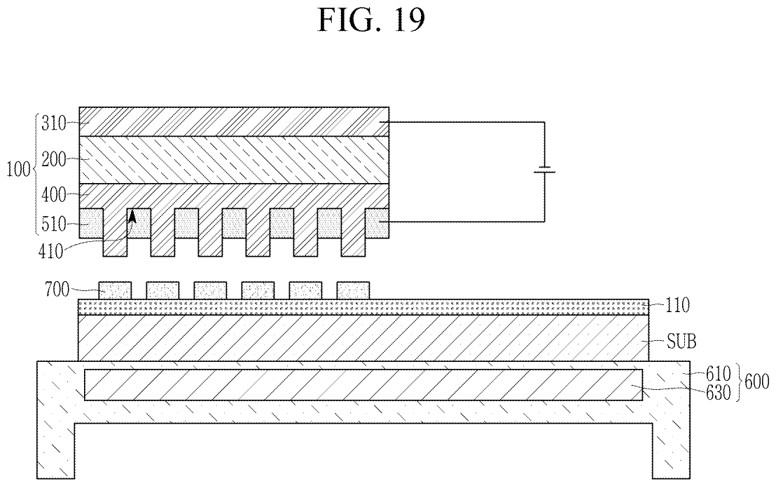

Referring to FIG. 19, the electrical connection between the conductive pattern 510 and the lower conductive plate 630 may be released or disconnected from each other, and the conductive plate 310 and the conductive pattern 510 may be electrically connected to each other. Therefore, the electrical attraction between the lower conductive plate 630 and the conductive pattern 510 may be reduced, and the electrical attraction may be formed between the conductive plate 310 and the conductive pattern 510, so that the conductive pattern 510 may be conductive, and the conductive pattern 510 may move to a position close to the conductive plate 310. For example, the conductive pattern 510 may move inside the groove 410 of the mold 400.

In the previous embodiment, the case of including both the conductive plate 310 and the lower conductive plate 630 has been described, but the case of including only one of the conductive plate 310 and the lower conductive plate 630 will be described later.

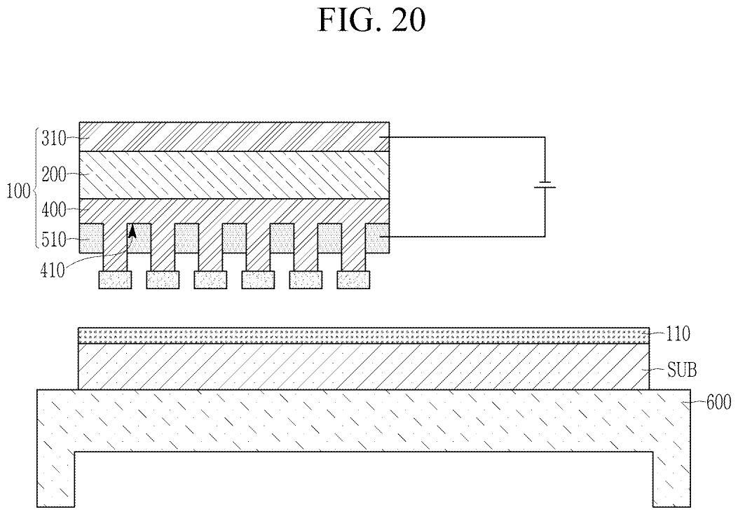

FIGS. 20, 21, 22, 23, and 24 illustrate the transfer method of a light emitting device according to another embodiment.

Referring to FIG. 20, the transfer substrate 100 and the transfer stage 600 may be prepared. The transfer stage 600 is the same as the embodiment of FIG. 15 except that the lower conductive plate 630 is not included. A detailed description of the same component is omitted for descriptive convenience.

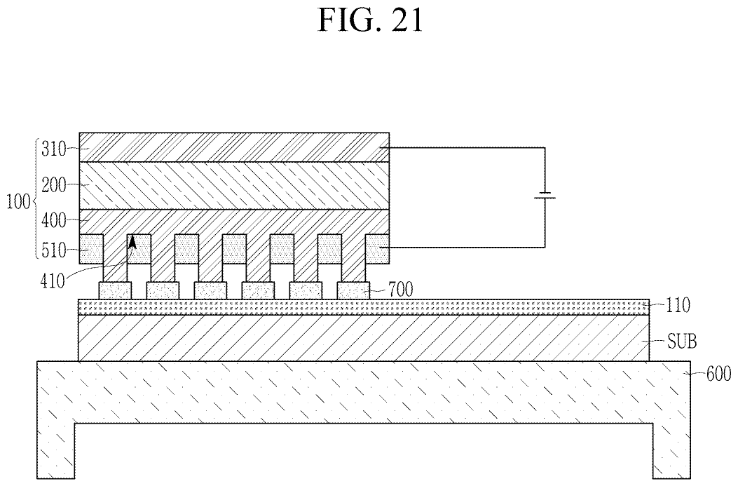

Referring to FIG. 21, the transfer substrate 100 may be moved to place the light emitting device 700 on the substrate SUB. In this step, the light emitting device 700 may adhere to the adhesive layer 110 of the substrate SUB. The conductive plate 310 and the conductive pattern 510 may be electrically connected to each other. For example, opposite voltages may be applied to the conductive plate 310 and the conductive pattern 510. For example, in case that a positive voltage is applied to the conductive plate 310, a negative voltage may be applied to the conductive pattern 510. Accordingly, the conductive pattern 510 may be positioned inside the groove 410 of the mold 400 by this electrical attraction.

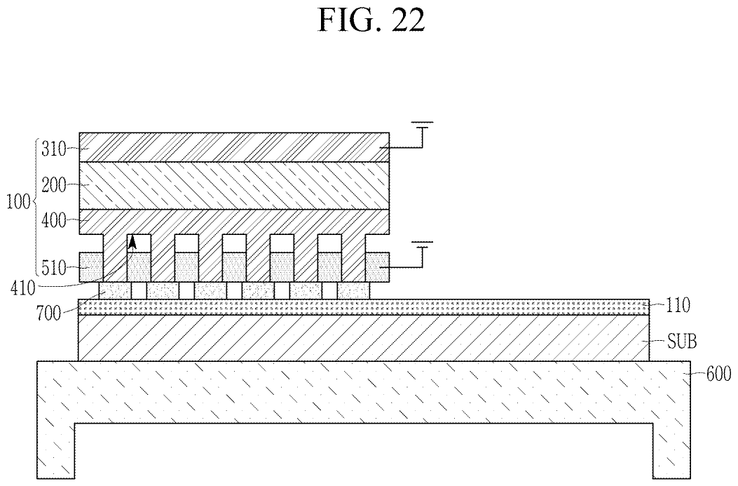

Referring to FIG. 22, the same voltage may be applied to the conductive plate 310 and the conductive pattern 510. For example, in detail, the same voltage may be applied to the conductive plate 310 and the conductive pattern 510. For example, in case that a positive voltage is applied to the conductive plate 310, a positive voltage may be also applied to the conductive pattern 510. In this process, an electrical repulsive force may be generated between the conductive plate 310 and the conductive pattern 510, and the conductive pattern 510 may move in a direction away from the conductive plate 310. For example, the conductive pattern 510 may move outside the groove 410 of the mold 400.

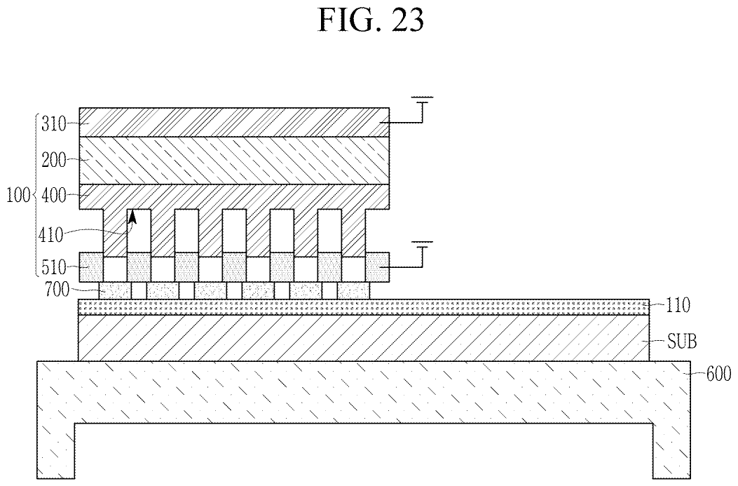

FIG. 23 shows that the conductive pattern 510 is moved to the outside of the groove 410 of the mold 400 by the electrical repulsive force between the conductive plate 310 and the conductive pattern 510. By the movement of the conductive pattern 510, the conductive pattern 510 may push the light emitting device 700, and thus the light emitting device 700 may be separated from the mold 400 and attached (or coupled) to the adhesive layer 110. For example, the light emitting device 700 may be well attached (or coupled) to the adhesive layer 110 by the pressure caused by the movement of the conductive pattern 510, and all transfer may be performed without missing the light emitting device 700.

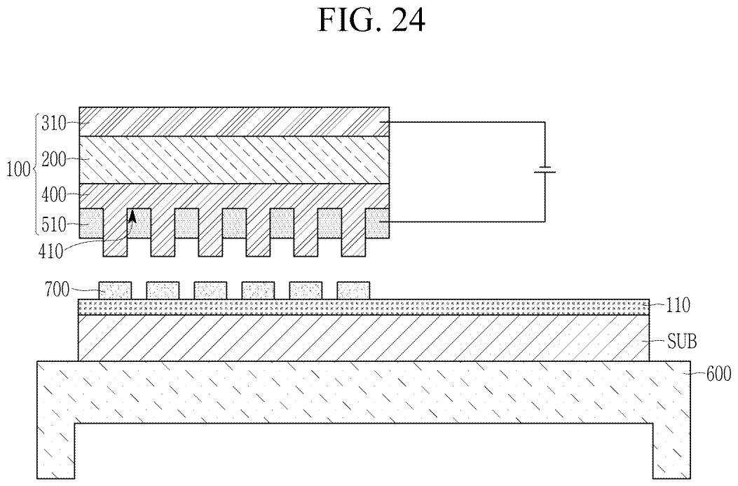

Referring to FIG. 24, opposite voltages may be applied to the conductive plate 310 and the conductive pattern 510 again. Through this, an electrical attraction may be formed between the conductive plate 310 and the conductive pattern 510, and the conductive pattern 510 may move to a position close to the conductive plate 310. For example, the conductive pattern 510 may move inside the groove 410 of the mold 400.

For example, the embodiments according to FIGS. 20, 21, 22, 23, and 24 may not include the lower conductive plate 630, and apply different voltages to the conductive plate 310 and the conductive pattern 510 at each step to generate a light emitting device through electrical attraction/repulsion.

The transfer method according to FIGS. 20, 21, 22, 23, and 24 may not include the lower conductive plate 630, but in other embodiments, the conductive plate 310 may not be included.

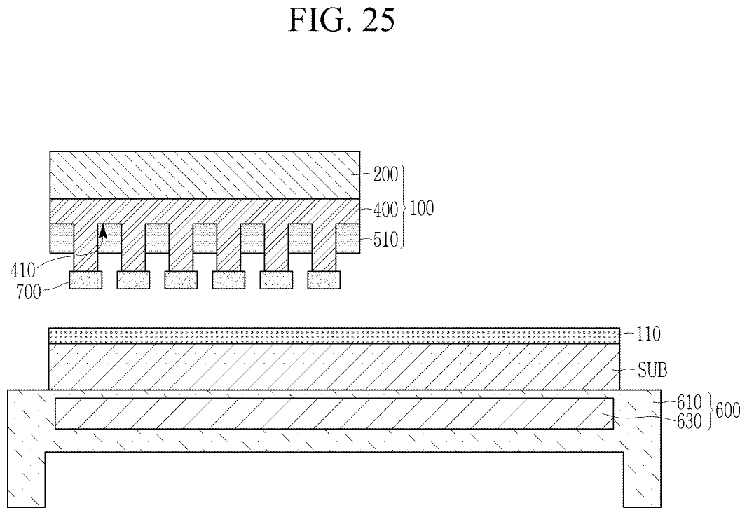

FIGS. 25, 26, 27, 28, and 29 show schematic cross-sectional views illustrating the transfer method of the light emitting device according to another embodiment.

Referring to FIG. 25, the transfer substrate 100 and the transfer stage 600 may be prepared. The transfer substrate 100 is the same as the embodiment FIG. 15 except that it does not include the conductive plate 310. A detailed description of the same component is omitted for descriptive convenience. In FIG. 25, the conductive pattern 510 may not receive a separate electrical attraction or magnetic force, so the conductive pattern 510 may be fixed to the groove 410 of the mold 400 through a separate fixing member.

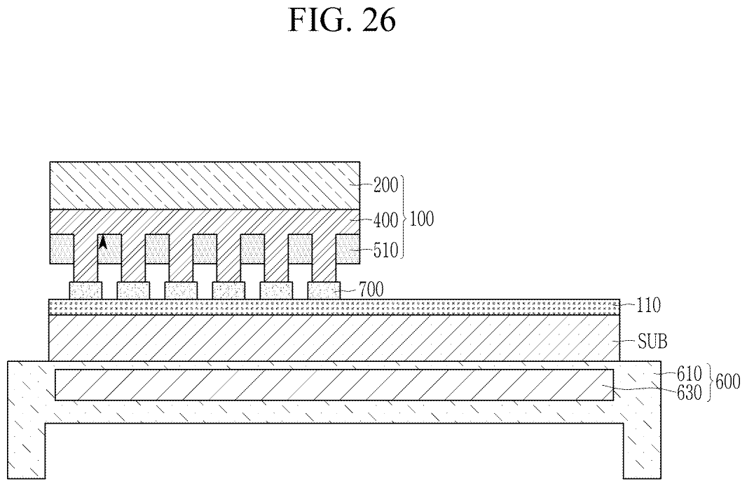

Referring to FIG. 26, the transfer substrate 100 may be moved to place the light emitting device 700 on the substrate SUB. In this step, the light emitting device 700 may adhere to the adhesive layer 110 of the substrate SUB.

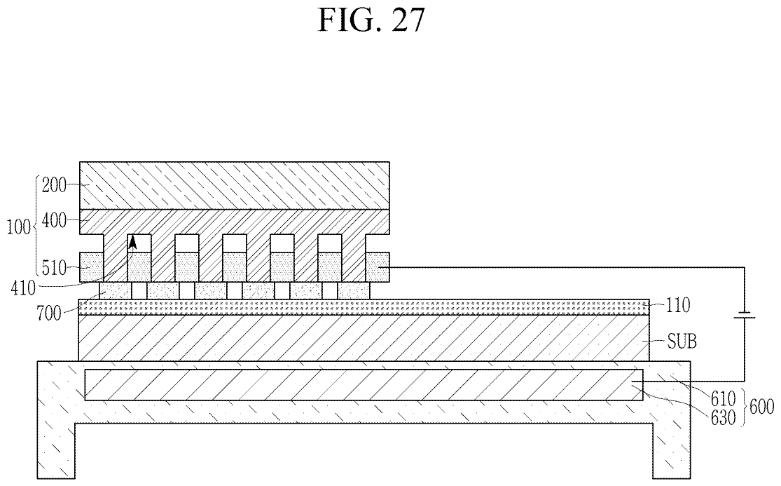

Referring to FIG. 27, different voltages may be applied to the lower conductive plate 630 and the conductive pattern 510. For example, voltages opposite to each other may be applied to the lower conductive plate 630 and the conductive pattern 510. For example, in case that a positive voltage is applied to the lower conductive plate 630, a negative voltage may be applied to the conductive pattern 510, and so on. In this process, electrical attraction between the lower conductive plate 630 and the conductive pattern 510 may be generated, and the conductive pattern 510 may move closer to the lower conductive plate 630. For example, the conductive pattern 510 may move outside the groove 410 of the mold 400.

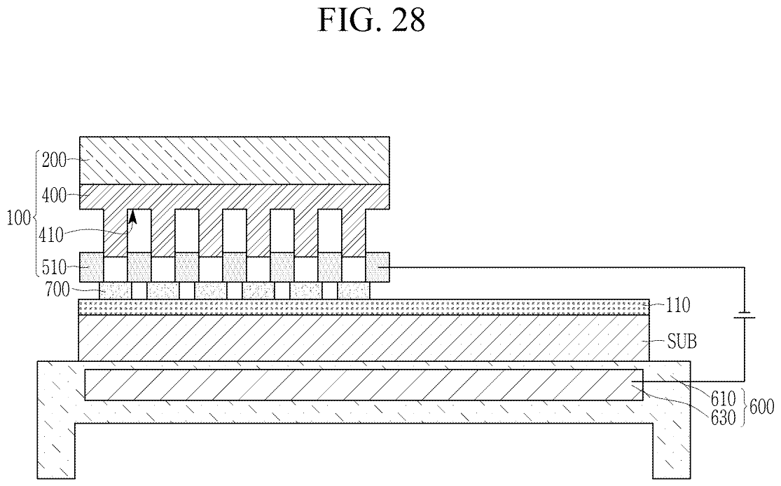

FIG. 28 shows that the conductive pattern 510 may move outward from the groove 410 of the mold 400 due to the electrical attraction between the lower conductive plate 630 and the conductive pattern 510. By the movement of the conductive pattern 510, the conductive pattern 510 may push the light emitting device 700, and thus the light emitting device 700 may be separated from the mold 400 and attached to the adhesive layer 110. For example, the light emitting device 700 may be well attached to the adhesive layer 110 by the pressure caused by the movement of the conductive pattern 510, and all transfers may be performed without missing the light emitting device 700.

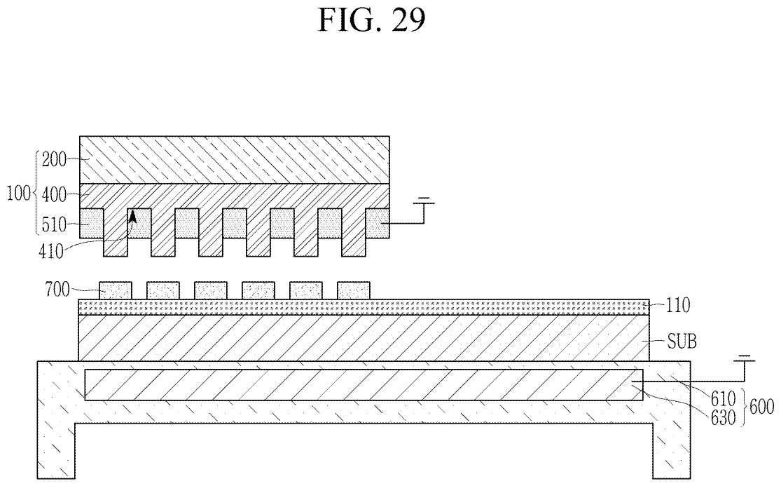

Next, referring to FIG. 29, the same voltage may be applied to the lower conductive plate 630 and the conductive pattern 510 again. Through this, an electrical repulsive force may be formed between the lower conductive plate 630 and the conductive pattern 510, and the conductive pattern 510 may move to a position away from the lower conductive plate 630. For example, the conductive pattern 510 may move inside the groove 410 of the mold 400.

For example, the embodiments according to FIGS. 25, 26, 27, 28, and 29 may not include the conductive plate 310, and apply different voltages to the lower conductive plate 630 and the conductive pattern 510 at each step to generate light emitting devices through electrical attraction/repulsion.

As described above, the transfer substrate 100 and the transfer method using the transfer substrate 100 according to the embodiment may push the light emitting device by magnetic force using a magnetic body 500 or electrical attraction using a conductive pattern 510, so that the light emitting device may be transferred without omission during transfer.

Therefore, transfer may be performed well, and since a separate repair process may not be required, this may be economical.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A transfer substrate comprising:
a base substrate;
a magnetic plate disposed on a surface of the base substrate;
a mold disposed on another surface of the base substrate and including a plurality of grooves; and
a magnetic body disposed in the plurality of grooves of the mold.

2. The transfer substrate of claim 1, wherein
the magnetic body has a plate shape and includes a plurality of openings, and
the mold is coupled to the plurality of openings of the magnetic body.

3. The transfer substrate of claim 1, wherein
the magnetic plate is disposed in a detachable form away from the base substrate.

4. The transfer substrate of claim 1, wherein
the magnetic plate and the magnetic body have magnets having different polarities.

5. The transfer substrate of claim 1, wherein
the magnetic body is movable inside the mold.

6. A transfer substrate comprising:
a base substrate;
a conductive plate disposed on a side of the base substrate;
a mold disposed on another side of the base substrate and including a plurality of grooves; and
a conductive pattern disposed in the plurality of grooves of the mold.

7. The transfer substrate claim 6, wherein
the conductive plate and the conductive pattern are electrically connected to each other.

8. The transfer substrate of claim 6, wherein
the conductive pattern has a plate shape and includes a plurality of openings, and
the mold is coupled to the plurality of openings of the conductive pattern.

9. A transfer substrate comprising:
a mold disposed on a side of a base substrate and including a plurality of grooves; and
a conductive pattern disposed in the plurality of grooves of the mold.

10. The transfer substrate of claim 9, wherein
the conductive pattern has a plate shape and includes a plurality of openings; and
the mold is coupled to the plurality of openings of the conductive pattern.

11. A transfer method comprising:
preparing a transfer substrate including:
a base substrate,
a magnetic plate disposed on a surface of the base substrate,
a mold disposed on another surface of the base substrate and including a plurality of grooves, and
a magnetic body disposed in the plurality of grooves of the mold;
attaching a transfer object to the mold;
placing the transfer substrate on a transfer stage including a lower magnetic plate; and
separating the magnetic plate from the surface of the base substrate.

12. The transfer method of claim 11, wherein in the step of separating the magnetic plate from the surface of the base substrate,
the magnetic body moves to be closer to the transfer stage to press the transfer object toward the transfer stage, and
the transfer object is transferred to a substrate disposed on the transfer stage.

13. The transfer method of claim 12, further comprising:
reattaching the magnetic plate to the surface of the base substrate after separating the magnetic plate from the surface of the base substrate.

14. The transfer method of claim 13, wherein
in the step of reattaching the magnetic plate to the surface of the base substrate, the magnetic body moves to be closer to the magnetic plate and moves to be farther away from the transfer stage.

15. A transfer method comprising:
preparing a transfer substrate including:
a base substrate,
a conductive plate disposed on a surface of the base substrate,
a mold disposed on another surface of the base substrate and including a plurality of grooves, and
a conductive pattern disposed in the grooves of the mold;
attaching a transfer object to the mold;
placing the transfer substrate on a transfer stage including a lower conductive plate; and
electrically connecting the lower conductive plate and the conductive pattern.

16. The transfer method of claim 15, wherein in the step of preparing the transfer substrate,
the conductive plate and the transfer substrate are electrically connected to each other, and
an electrical attraction is generated between the conductive plate and the transfer substrate.

17. The transfer method of claim 16, further comprising:
disconnecting the electrical connection between the conductive plate and the transfer substrate before electrically connecting the lower conductive plate and the conductive pattern,
wherein, in the step of electrically connecting the lower conductive plate and the conductive pattern, due to an electrical attraction between the lower conductive plate and the conductive pattern, the conductive pattern moves to be closer to the transfer stage to transfer the transfer object to be transferred toward the transfer stage.

18. The transfer method of claim 15, further comprising:
disconnecting the electrical connection between the lower conductive plate and the conductive pattern and electrically connecting the conductive plate and the conductive pattern after electrically connecting the lower conductive plate and the conductive pattern.

19. A transfer method comprising:
preparing a transfer substrate including:
a base substrate,
a mold disposed on a side of the base substrate and including a plurality of grooves, and
a conductive pattern disposed in the grooves of the mold;
attaching a transfer object to the mold;
placing the transfer substrate on a transfer stage including a lower conductive plate; and
electrically connecting the lower conductive plate and the conductive pattern.

20. A transfer method comprising:
preparing a transfer substrate including:
a base substrate,
a conductive plate disposed on a surface of the base substrate,
a mold disposed on another surface of the base substrate and including a plurality of grooves, and
a conductive pattern disposed in the plurality of grooves of the mold and electrically connected to the conductive plate;
attaching a transfer object to the mold;
placing the transfer substrate on a transfer stage; and
disconnecting an electrical connection between the conductive plate and the conductive pattern.
